(19) United States
(12) Patent Application Publication
(10) Pub. No.: US 2006/0154439 A1
(43) Pub. Date: Jul. 13, 2006

(54) Method of fabricating semiconductor device

(75) Inventor: Chung-Ho Lim, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/330,747

(22) Filed: Jan. 12, 2006

(30) Foreign Application Priority Data
Jan. 13, 2005 (KR) 10-2005-0003355

(51) Int. Cl. H01L 21/76

(52) U.S. Cl. 438/424; 438/435; 438/437

(57) ABSTRACT

In a method of fabricating a semiconductor device, trenches are formed defining active regions at predetermined portions of a semiconductor substrate. A thermal oxide layer and a liner layer are sequentially formed covering inner walls of the trenches and upper surfaces of the active regions. Device isolation patterns are formed filling the trenches, in which the liner layer is formed, and an upper portion of the liner layer at the upper portions of the active regions are exposed. The exposed liner layer is dry etched to expose an upper portion of the thermal oxide layer at the upper portions of the active regions. The exposed thermal oxide layer is etched to expose the upper surfaces of the active regions.

### CROSS-REFERENCE TO RELATED APPLICATIONS

This U.S. non-provisional patent application claims priority under 35 U.S.C. § 119 of Korean Patent Application 10-2005-0003355 filed on Jan. 13, 2005, the entire contents of which are hereby incorporated by reference.

### BACKGROUND OF THE INVENTION

1. Field of the Invention

The present invention relates to a method of fabricating a semiconductor device, and more particularly, to a method of forming an active region of a semiconductor device to have a rounded upper edge without any indentations.

2. Description of the Related Art

In the fabrication of a semiconductor device, a silicon nitride layer is used for various purposes. Specifically, since a silicon nitride layer formed using low pressure chemical vapor deposition (LPCVD) has high density (2.9-3.1 g/cm³), such a layer can be used for a diffusion barrier layer or a passivation layer. In addition, since a silicon nitride layer has good etch selectivity with respect to a silicon oxide layer or a silicon layer, it can be used as an etch mask in etching the silicon oxide layer or the silicon layer. These characteristics of the silicon nitride layer make such a layer useful for device isolation, which will be described below.

The device isolation process includes sequential operations for electrically isolating neighboring electronic elements. A trench isolation technology is most widely used because it can satisfy the need for high integration of the semiconductor device. According to the trench isolation technology for electrically isolating adjacent transistors, trenches are formed on a semiconductor substrate to a predetermined depth, and the trenches are filled with an insulating layer. At this time, the transistors are formed in active regions defined between the trenches, and the insulating layer filling the trenches electrically isolates the transistors from one another.

As described above, since the silicon nitride layer has good etch selectivity with respect to the silicon layer, it can be used as an etch mask in forming the trenches. Meanwhile, impurities such as oxygen and carbon can penetrate the semiconductor substrate through sidewalls of the trenches and thus electrical characteristics of the transistors can be changed. However, since a silicon nitride layer has good diffusion barrier characteristics, it can prevent impurity penetration.

In spite of these advantages of the silicon nitride layer, many particles are generated during wet etching of the silicon nitride layer. Further, indentations can be caused during wet etching of a silicon nitride liner in the device isolation process.

FIGS. 1 to 3 are sectional views illustrating a conventional method of forming a trench device isolation layer.

Referring to FIG. 1, trench mask patterns 20 are formed on a semiconductor substrate 10 by stacking a pad oxide pattern 22 and a polishing stop pattern 24 in sequence. The polishing stop pattern 24 is formed of a silicon nitride layer and the pad oxide pattern 22 is formed of a silicon oxide layer.

Trenches 30 defining active regions are formed by anisotropic etching of the semiconductor substrate 10 using the trench mask pattern 20 as an etch mask. A thermal oxide layer 40 and a liner layer 50 are sequentially formed on the resulting structure in which the trenches are formed. Preferably, the thermal oxide layer 40 is formed of a silicon oxide layer by a thermal oxidation process. Etch damage of the inner walls of the trenches 30 can be caused during formation of the trenches. Etch damage to the trenches 30 can be cured by the thermal oxidation process.

Preferably, the liner layer 50 is formed of a silicon nitride layer by a CVD process. Accordingly, as illustrated in FIG. 1, the liner layer 50 is conformally formed on an entire surface of the resulting structure in which the thermal oxide layer 40 is formed.

Meanwhile, since the thermal oxidation process is performed in a state in which the trench mask pattern 20 covers the active region, oxygen is not uniformly supplied to the active region. Accordingly, as illustrated in FIG. 4, an upper edge 88 of the active region has an angular shape, and concentration of an electric field in this region due to this shape adversely affects electrical characteristics of the transistor.

Referring to FIG. 2, a device isolation layer is formed and planarized until the trench mask patterns 20 are exposed, thereby forming device isolation patterns 60 filling the trenches 30. The device isolation layer is formed of a silicon oxide layer, and the planarization etching is performed using a chemical mechanical polishing (CMP) with an etch selectivity with respect to the polishing stop pattern 24.

While forming the device isolation patterns 60, the liner layer 50 is also patterned to form liner patterns 55 enclosing a lower surface and side surface of the device isolation patterns 60. Consequently, the device isolation patterns 60, the polishing stop patterns 24, and the upper surfaces of the liner patterns 55 interposed therebetween are exposed.

Referring to FIG. 3, the exposed polishing stop patterns 24 are etched using a wet etching solution having an etch selectivity with respect to a silicon oxide layer until the upper surfaces of the pad oxide patterns 22 are exposed. For example, phosphoric acid solution is used to etch the polishing stop patterns 24. Although not shown in FIG. 3, the pad oxide patterns 22 are removed to expose upper surfaces of the active regions, and a gate oxide layer is further formed on the exposed active regions by a thermal oxidation process.

As described above, the silicon nitride layer has good etch selectivity with respect to the silicon oxide layer. Therefore, if any portions of the polishing stop patterns 24 remain on the pad oxide pattern 22, the operation of removing the pad oxide patterns 22 is performed incompletely. To ensure complete removal, the operation of removing the pad oxide patterns 22 is performed using an over-etching process. In this case, however, indentations 70 are formed on the liner patterns 55. Such indentations 70 can cause defects during post-processing or can badly affect transistor characteristics.

### SUMMARY OF THE INVENTION

The present invention provides a method of fabricating a semiconductor substrate, in which a device isolation layer defining an active region can be formed without indentations.

The present invention also provides a method of fabricating a semiconductor substrate, in which an active region with a rounded upper edge can be formed without indentations.

In one aspect of the present invention, a method of fabricating a semiconductor device is provided. Trenches are formed defining active regions at predetermined portions of a semiconductor substrate. A thermal oxide layer and a liner layer are sequentially formed covering inner walls of the trenches and upper surfaces of the active regions. Device isolation patterns are formed filling the trenches, in which the liner layer is formed, and an upper portion of the liner layer at the upper portions of the active regions are exposed. The exposed liner layer is dry etched to expose an upper portion of the thermal oxide layer at the upper portions of the active regions. The exposed thermal oxide layer is etched to expose the upper surfaces of the active regions.

In one embodiment, forming the trenches includes: forming mask patterns at the upper portions of the active regions; forming the trenches defining the active regions by anisotropic etching of the semiconductor substrate using the mask patterns as an etch mask; and removing the mask patterns to expose the active regions.

In another embodiment, removing the mask patterns completely exposes an entire surface of the semiconductor substrate in which the trenches are formed.

In another embodiment, the thermal oxide layer is formed following complete exposure of an entire surface of the semiconductor substrate in which the trenches are formed.

In another embodiment, forming the liner layer includes conformally forming a silicon nitride layer with an etch selectivity with respect to the thermal oxide layer.

In another embodiment, forming the device isolation patterns includes: forming a device isolation layer filling the trenches on the resulting structure in which the liner layer is formed; and dry etching the device isolation layer using an etch recipe with high etch selectivity with respect to the liner layer until the upper portion of the liner layer is exposed.

In another embodiment, forming the device isolation patterns further includes, before the dry etching of the device isolation layer, planarizing the device isolation layer to an extent such that the upper portion of the line layer is not exposed.

In another embodiment, an etch stop point of the dry etching of the device isolation layer is determined using a dry etching recipe with high etch selectivity with respect to the liner layer by controlling composition of an etch reaction gas.

In another embodiment, the method further comprises, before etching the thermal oxide layer, performing an ion implantation process of implanting impurities into the active regions by using the thermal oxide layer as a buffer layer.

In another embodiment, the method further comprises, after etching the thermal oxide layer, forming a gate oxide layer on the exposed upper portion of the active regions using a thermal oxidation process.

In another aspect, the present invention is directed to a method of fabricating a semiconductor memory device. Mask patterns are formed on a semiconductor substrate. Trenches are formed that define active regions by anisotropic etching of the semiconductor substrate using the mask patterns as an etch mask. The mask patterns are removed to expose the active regions. A thermal oxide layer and a liner layer are sequentially formed covering upper portions of the active regions and inner walls of the trenches on the resulting structure in which the upper portions of the active regions are exposed. A device isolation layer is formed filling the trenches on the liner layer. The device isolation layer is etched to expose an upper surface of the liner layer and to form device isolation patterns filling the trenches. The liner layer is dry etched to expose the upper portion of the thermal oxide layer at the upper portions of the active regions. The exposed thermal oxide layer is etched to expose the upper portions of the active regions. A gate oxide layer is formed on the exposed upper portions of the active regions.

In one embodiment, removing the mask patterns completely exposes an entire surface of the semiconductor substrate in which the trenches are formed, and wherein the thermal oxide layer is formed following complete exposure of an entire surface of the semiconductor substrate in which the trenches are formed.

In another embodiment, forming the device isolation patterns includes: planarizing the device isolation layer to an extent such that the upper portion of the liner layer is not exposed; and dry etching the planarized device isolation layer using an etch recipe with high etch selectivity with respect to the liner layer until the upper portion of the liner is exposed.

In another embodiment, dry etching the planarized device isolation layer determines an etch stop point thereof by controlling composition of an etch reaction gas.

In another embodiment, an etch stop point of the dry etching of the liner layer is determined using a dry etching recipe with high etch selectivity with respect to the thermal oxide layer by controlling composition of an etch reaction gas.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings:

FIGS. 1 to 3 are sectional views illustrating a conventional method of forming a trench device isolation layer;

FIG. 4 is a microscopic photograph of a conventional active region;

FIG. 5 is a flow diagram illustrating a method of forming a trench device isolation layer according to a preferred embodiment of the present invention; and

FIGS. 6 to 14 are sectional views illustrating the method of forming the trench device isolation layer according to the preferred embodiment of the present invention.

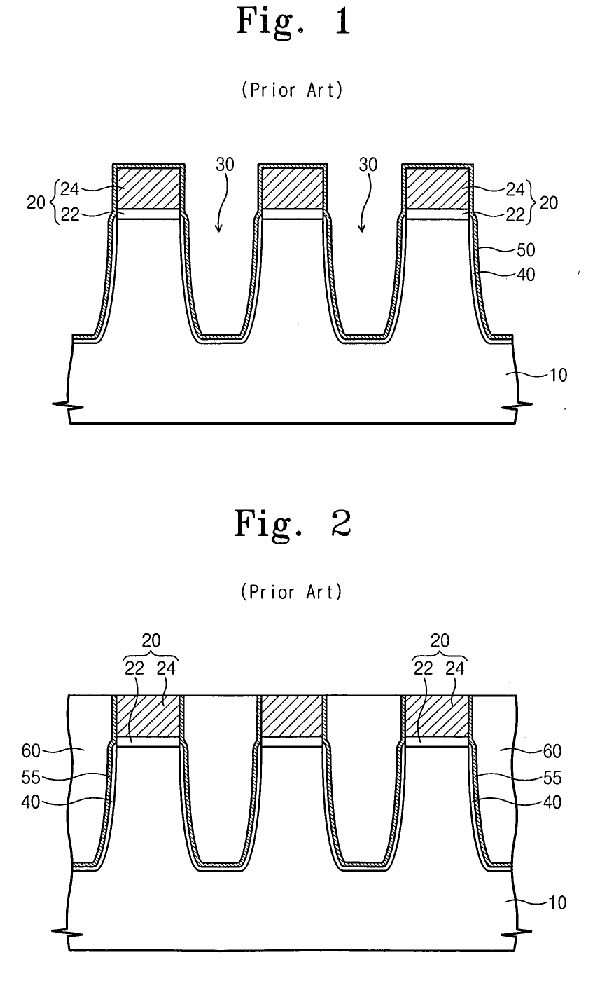

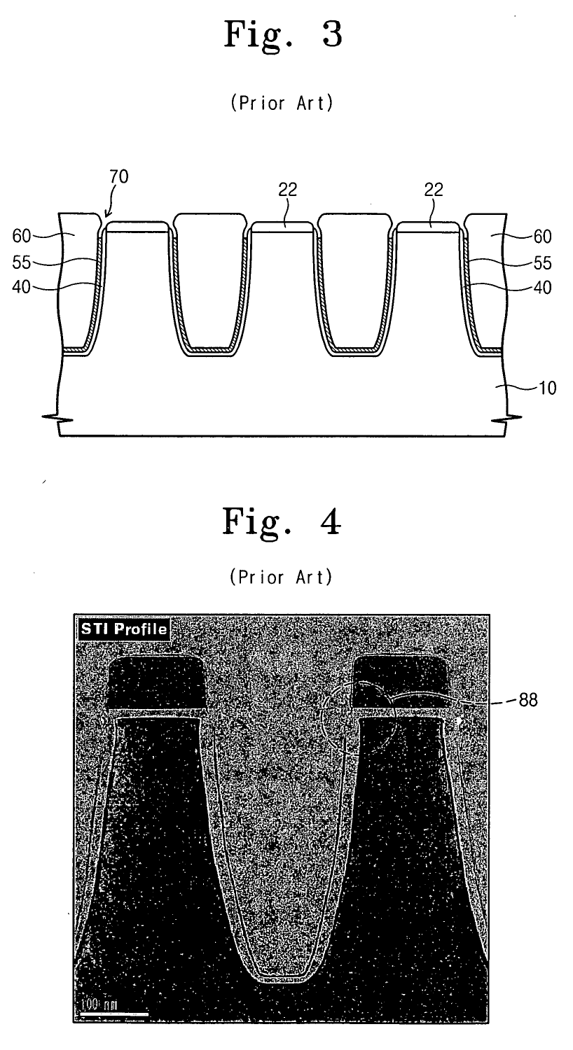

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

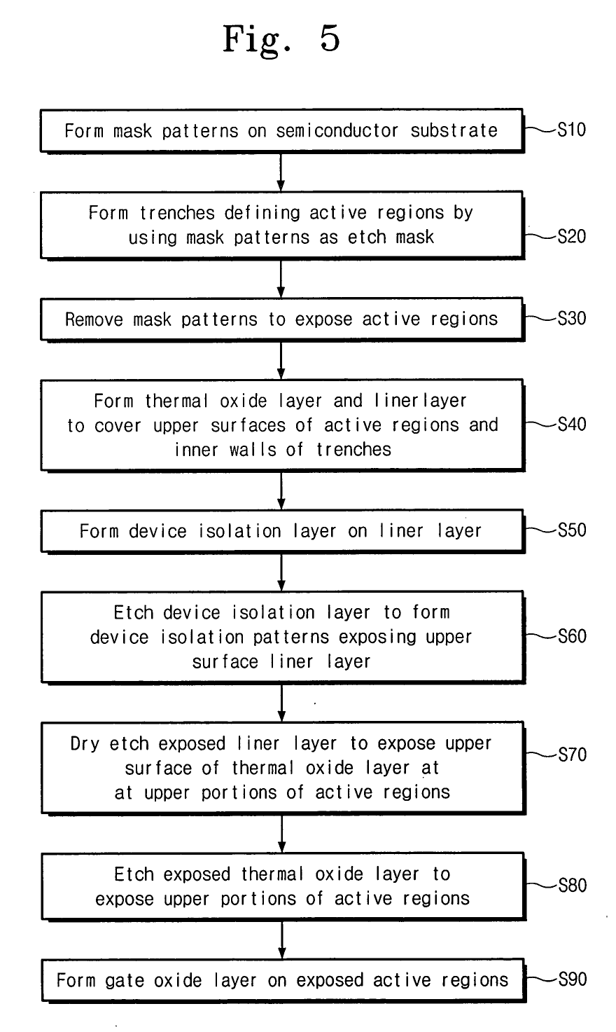

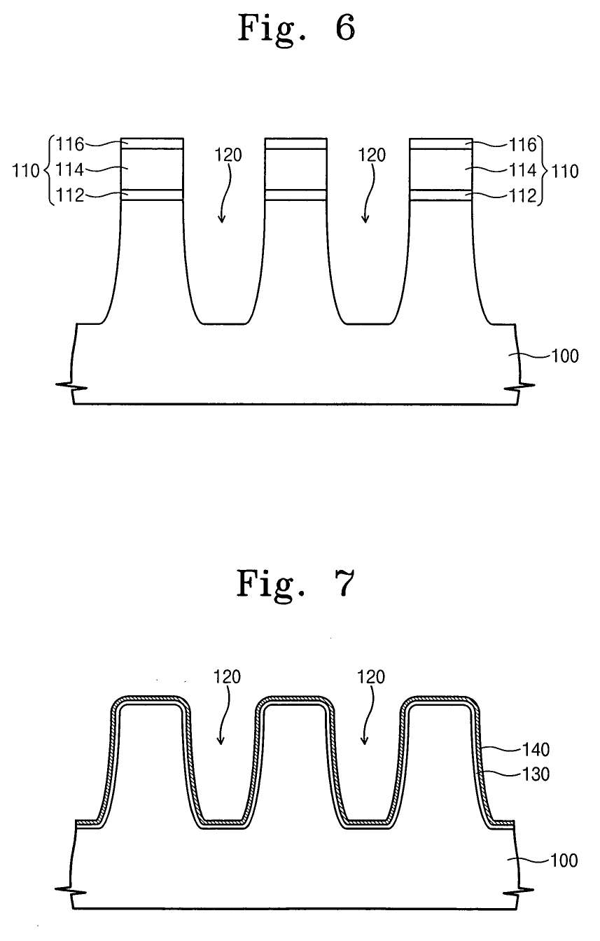

FIG. 5 is a flow diagram illustrating a method of forming a trench device isolation layer according to a preferred embodiment of the present invention, and FIGS. 6 to 14 are sectional views illustrating the method of forming the trench device isolation layer according to the preferred embodiment of the present invention.

Referring to FIGS. 5 and 6, mask patterns 110 defining active regions are formed on a predetermined upper portion of a semiconductor substrate 100 (operation S10). The mask patterns 110 can include a pad oxide layer 112 and a reflection barrier layer 116, which are stacked in sequence.

Preferably, the pad oxide layer 112 is formed of a silicon oxide layer by a thermal oxidation process or a chemical vapor deposition (CVD) process, and the reflection barrier layer 116 is formed of a silicon nitride layer by a CVD process. The reflection barrier layer 116 controls reflectivity during a photolithography process of forming the mask patterns 110. In a modified embodiment, a hard mask layer 114 formed of a silicon nitride layer can be further interposed between the reflection barrier layer 116 and the pad oxide layer 112.

Trenches 120 defining the active regions are formed by anisotrophic etching of the semiconductor substrate 100 using the mask patterns 110 as an etch mask (operation S20). The etching operation of forming the trenches 120 can include dry etching the semiconductor substrate 100 using an etch recipe having an etch selectivity with respect to the reflection barrier layer 116 and/or the hard mask layer 114. In this operation, the reflection barrier layer can be interposed.

Referring to FIGS. 5 and 7, after forming the trenches 120, the mask patterns 110 are removed to expose upper surfaces of the active regions and inner walls of the trenches 120 (operation S30).

The operation of removing the mask patterns 110 is achieved by wet etching using an etch recipe with an etch selectivity with respect to the semiconductor substrate 100. In an embodiment, the reflection barrier 116 and hard mask 114 are removed using a cleaning solution containing phosphoric acid, and the pad oxide layer 112 is removed using a cleaning solution containing fluoric acid. In addition, after removing the pad oxide layer 112, a cleaning operation can be further performed for removing foreign particles.

By removing the mask patterns 110, the entire surface of the semiconductor substrate 100 in which the trenches 120 are formed is exposed. This technical characteristic of the present invention is different from that of the prior art approach in which the mask patterns 110 are not removed in this operation.

A thermal oxide layer 130 is formed on the entire surface of the semiconductor substrate 100 by a thermal oxidation of the resulting structure in which the mask patterns are removed (operation S40). The thermal oxidation process cures any etch damage that has occurred to the inner walls of the trenches 120, which can be caused during the anisotrophic etching process. Specifically, since the thermal oxidation process is performed in a state in which the upper portion of the active region is exposed, the upper edge of the active region can become rounded in profile.

A liner layer 140 is conformally formed on the resulting structure in which the thermal oxide layer 130 is formed. Preferably, the liner layer 140 is formed of a silicon nitride layer by a CVD process so as to prevent impurities from penetrating into the semiconductor substrate 100 in the subsequent operations. In addition, unlike the prior art, the liner layer 140 is used as an etch stop layer in a following etching operation of forming a device isolation layer.

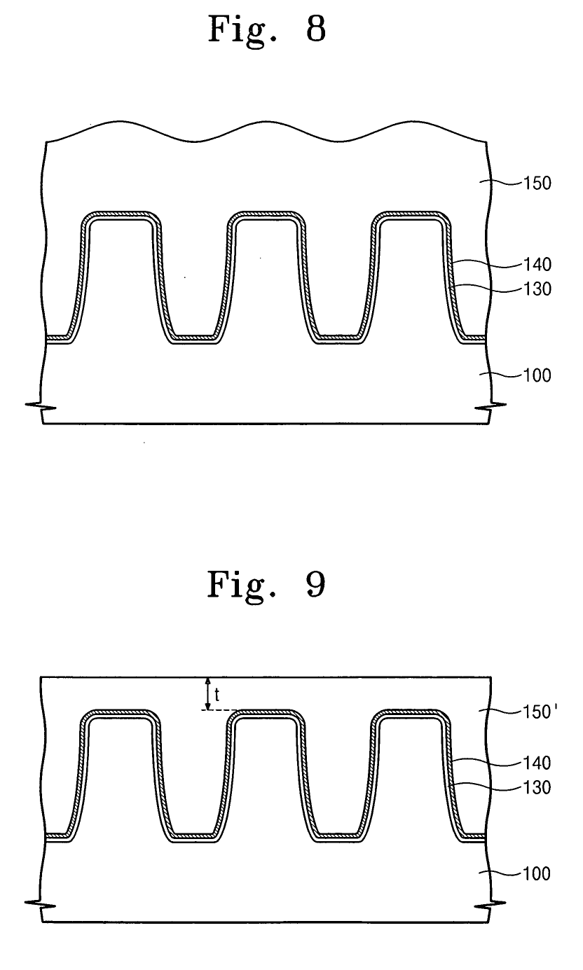

Referring to FIGS. 5 and 8, a device isolation layer 150 is formed on the liner layer 140 to fill the trenches 120 (operation S50). The device isolation layer 150 can be formed of at least one layer selected from the group consisting of various kinds of silicon oxide layers, various kinds of spin-on-glass (SOG) layers, and polycrystalline silicon layer. It is preferable that the device isolation layer 150 is formed of high density plasma (HDP) oxide to a thickness of about 2000 Å to about 5000 Å.

Referring to FIGS. 5 and 9, the device isolation layer 150 is entirely etched until a thickness t of the device isolation layer 150 becomes about 1500-1700 Å from the top of the active region (operation S60). For the convenience of subsequent operations, it is preferable that the remaining device isolation layer 150′ has a flat top surface. For this purpose, the surface etching of the entire upper surface of the device isolation layer 150′ can be performed using A CMP technology. Meanwhile, the thickness t of the device isolation layer 150′ can be controlled according to requirements of the fabrication process.

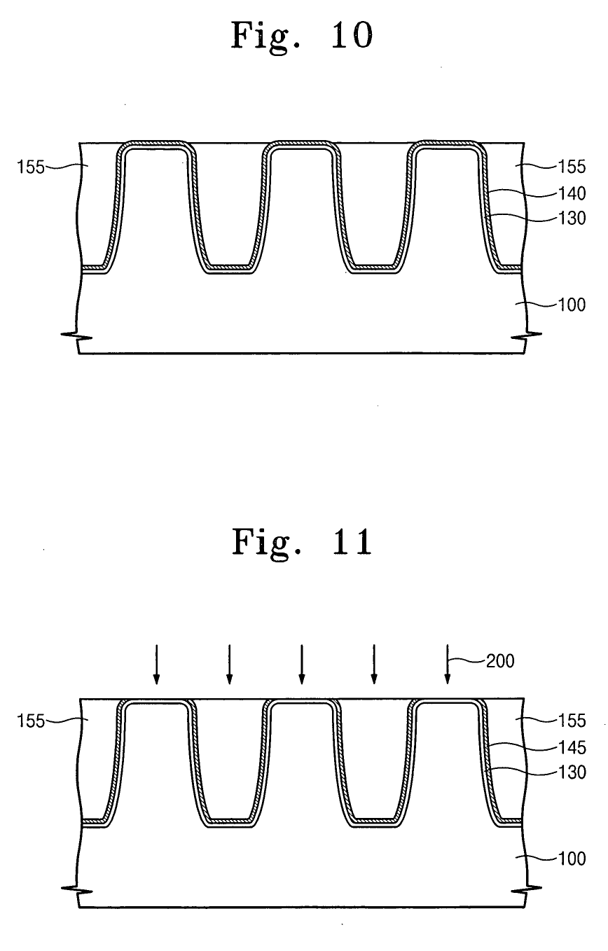

Referring to FIGS. 5 and 10, the remaining device isolation layer 150′ is dry etched until the upper surface of the liner layer 140 is exposed (operation S60). Accordingly, device isolation patterns 155 that are locally arranged inside the trenches 120 are formed. The device isolation patterns 155 electrically isolate the active regions.

The dry etching of the device isolation layer 150′ is performed using an etch recipe having a high etch selectivity with respect to the liner layer 140 until the liner layer 140 is exposed. According to the embodiments of the present invention, the dry etching is performed using an over etching process so as to prevent the device isolation layer 150′ from remaining on the active regions. In spite of the over etching, the thickness of the liner layer 140 can be minimized because of the high etch selectivity. In addition, unlike a wet etching process in which an etch stop point is determined by an etch time, the etch stop point can be determined more accurately because the device isolation patterns 155 are formed using the dry etching. Therefore, any height difference between the device isolation pattern 155 and the top surface of the liner layer 140 can be minimized. In the operation of forming the device isolation pattern 155, the etch stop point can be determined by changing the composition of an etch reaction gas until the underlying liner layer 140 is exposed.

Referring to FIGS. 5 and 11, the exposed liner layer 140 is dry etched to form liner patterns exposing the pad oxide layer 130 at the upper portions of the active regions (operation S70).

The operation of forming the liner patterns 145 includes dry etching the silicon nitride layer using an etch recipe with high etch selectivity with respect to the silicon oxide layer. In order to selectively etch the silicon nitride layer, the etching operation of forming the liner patterns 145 can use a process gas containing CH₂F₂ and CHF₃. The etching operation may further include Ar gas and oxygen gas.

The operation of forming the liner patterns 145 is performed using an over etching process to completely remove the liner layer 140 acting as an etch stop layer in an operation of etching the oxide layer. Accordingly, the pad oxide layer 130 can be exposed at the upper portions of the active regions. In spite of the over etching, recess of the pad oxide layer 130 and the device isolation pattern 155 can be minimized because the dry etching process has high etch selectivity.

In addition, unlike the wet etching in which an etch stop point is determined by an etch time, the etch stop point can be determined more accurately because the device isolation patterns 155 are formed using the dry etching. Therefore, the upper surface of the pad oxide layer 130 is exposed without any dents. Since a surface area of the exposed liner layer 140 is reduced, the etch stop point can be determined using a phenomenon that composition of an etch reaction gas is changed.

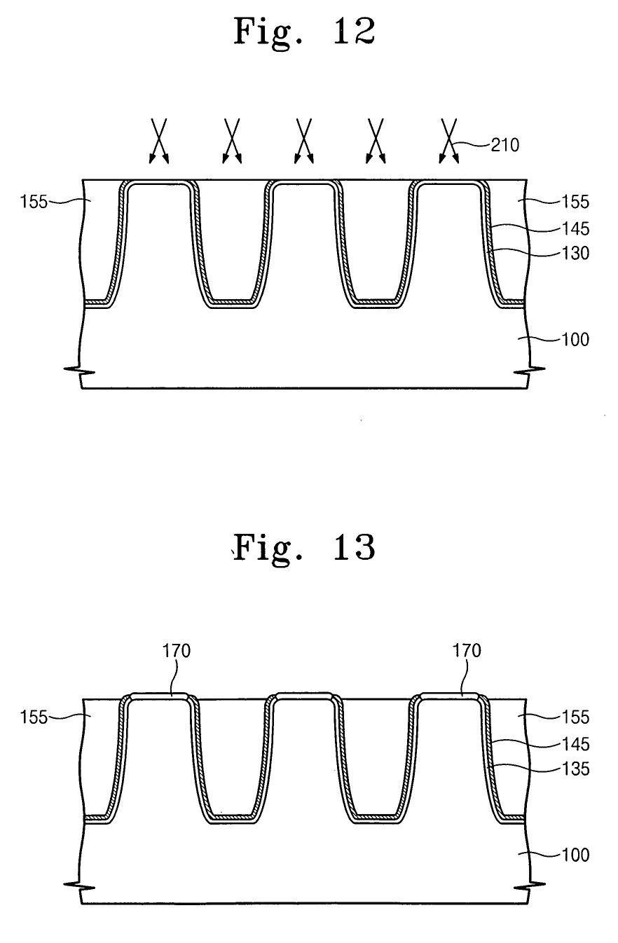

Referring to FIG. 12, impurities are implanted into the active region by ion implantation process 210 using the exposed pad oxide layer 130 as a buffer layer. The implanted impurities influence electrical characteristics of the transistors formed in the active regions. The ion implantation process may include an impurity implantation process for controlling a threshold voltage of the transistor. The pad oxide layer 130 is used as a buffer layer, and operates to minimize problems such as an ion channeling that can occur during the ion implantation processes.

Referring to FIGS. 5 and 13, pad oxide patterns 135 exposing the upper surfaces of the active regions are formed by etching the pad oxide layer 130 using an etch recipe with an etch selectivity with respect to the liner patterns 145 (operation S80). Then, a gate oxide layer 170 is formed on the exposed upper surfaces of the active regions (operation S90).

The operation of forming the pad oxide patterns 135 can include wet etching the silicon oxide layer using an etch recipe with an etch selectivity with respect to the silicon nitride layer. In addition, it is preferable that the gate oxide layer 170 is formed by thermally oxidizing silicon atoms of the exposed active regions.

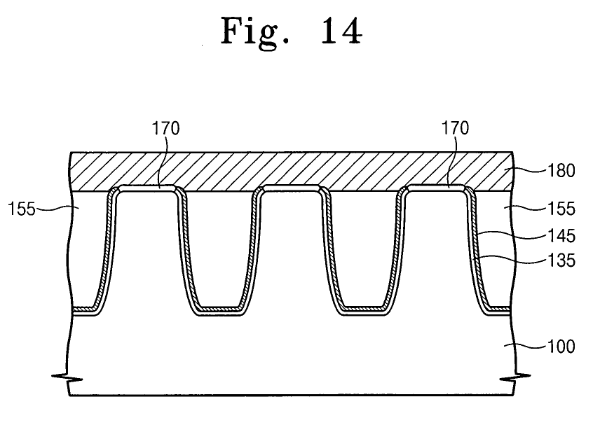

Referring to FIGS. 5 and 14, a gate electrode 180 is formed on the resulting structure in which the gate oxide layer 170 is formed. The operation of forming the gate electrode 180 includes forming a gate conductive layer on the resulting structure, and patterning the gate conductive layer in a direction crossing the active regions and the device isolation patterns 155. The gate conductive layer can be formed of at least one material selected from the group consisting of polycrystalline silicon, tungsten, tungsten silicide, cobalt silicide, copper, tungsten nitride, tantalum nitride, titanium nitride, titanium, and tantalum.

According to the present invention, the thermal oxidation process is performed after the mask patterns used for defining the trenches are completely removed. Thus, the upper area of the active regions exposed by the thermal oxidation process is widened. Consequently, the upper edges of the active regions can have the rounded shape, which is suitable for improved electrical characteristics of the transistor.

In addition, a dry etching process is performed to remove the liner layer at the upper portions of the active regions. Compared with the wet etching process, the dry etching process can accurately determine the etch stop point. Therefore, it is possible to prevent indentations from being formed at the upper portions of the liner patterns (that is, between the device isolation patterns and the active regions). Consequently, it is possible to form active regions that have a rounded upper edge without any indentations.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A method of fabricating a semiconductor device, comprising:
forming trenches defining active regions at predetermined portions of a semiconductor substrate;
sequentially forming a thermal oxide layer and a liner layer covering inner walls of the trenches and upper surfaces of the active regions;
forming device isolation patterns filling the trenches, in which the liner layer is formed, and exposing an upper portion of the liner layer at the upper portions of the active regions;
dry etching the exposed liner layer to expose an upper portion of the thermal oxide layer at the upper portions of the active regions; and
etching the exposed thermal oxide layer to expose the upper surfaces of the active regions.

2. The method of claim 1, wherein forming the trenches includes:
forming mask patterns at the upper portions of the active regions;
forming the trenches defining the active regions by anisotropic etching of the semiconductor substrate using the mask patterns as an etch mask; and
removing the mask patterns to expose the active regions.

3. The method of claim 2, wherein removing the mask patterns completely exposes an entire surface of the semiconductor substrate in which the trenches are formed.

4. The method of claim 1, wherein the thermal oxide layer is formed following complete exposure of an entire surface of the semiconductor substrate in which the trenches are formed.

5. The method of claim 1, wherein forming the liner layer includes conformally forming a silicon nitride layer with an etch selectivity with respect to the thermal oxide layer.

6. The method of claim 1, wherein forming the device isolation patterns includes:
forming a device isolation layer filling the trenches on the resulting structure in which the liner layer is formed; and
dry etching the device isolation layer using an etch recipe with high etch selectivity with respect to the liner layer until the upper portion of the liner layer is exposed.

7. The method of claim 6, wherein forming the device isolation patterns further includes, before the dry etching of the device isolation layer, planarizing the device isolation layer to an extent such that the upper portion of the line layer is not exposed.

8. The method of claim 6, wherein an etch stop point of the dry etching of the device isolation layer is determined using a dry etching recipe with high etch selectivity with respect to the liner layer by controlling composition of an etch reaction gas.

9. The method of claim 1, wherein an etch stop point of the dry etching of the liner layer is determined using a dry etching recipe with high etch selectivity with respect to the thermal oxide layer by controlling composition of an etch reaction gas.

10. The method of claim 1, further comprising, before etching the thermal oxide layer, performing an ion implantation process of implanting impurities into the active regions by using the thermal oxide layer as a buffer layer.

11. The method of claim 1, further comprising, after etching the thermal oxide layer, forming a gate oxide layer on the exposed upper portion of the active regions using a thermal oxidation process.

12. A method of fabricating a semiconductor memory device, comprising:
forming mask patterns on a semiconductor substrate;
forming trenches defining active regions by anisotropic etching of the semiconductor substrate using the mask patterns as an etch mask;
removing the mask patterns to expose the active regions;
sequentially forming a thermal oxide layer and a liner layer covering upper portions of the active regions and inner walls of the trenches on the resulting structure in which the upper portions of the active regions are exposed;
forming a device isolation layer filling the trenches on the liner layer;
etching the device isolation layer to expose an upper surface of the liner layer and to form device isolation patterns filling the trenches;
dry etching the liner layer to expose the upper portion of the thermal oxide layer at the upper portions of the active regions;
etching the exposed thermal oxide layer to expose the upper portions of the active regions; and
forming a gate oxide layer on the exposed upper portions of the active regions.

13. The method of claim 12, wherein removing the mask patterns completely exposes an entire surface of the semiconductor substrate in which the trenches are formed, and wherein the thermal oxide layer is formed following complete exposure of an entire surface of the semiconductor substrate in which the trenches are formed.

14. The method of claim 12, wherein forming the device isolation patterns includes:
planarizing the device isolation layer to an extent such that the upper portion of the liner layer is not exposed; and
dry etching the planarized device isolation layer using an etch recipe with high etch selectivity with respect to the liner layer until the upper portion of the liner is exposed.

15. The method of claim 14, wherein dry etching the planarized device isolation layer determines an etch stop point thereof by controlling composition of an etch reaction gas.

16. The method of claim 12, wherein an etch stop point of the dry etching of the liner layer is determined using a dry etching recipe with high etch selectivity with respect to the thermal oxide layer by controlling composition of an etch reaction gas.
